(19) United States
(12) Patent Application Publication
(10) Pub. No.: US 2008/0074835 A1
(43) Pub. Date: Mar. 27, 2008

(54) IMAGE-CAPTURING MODULE AND PORTABLE COMPUTER HAVING THE SAME

(75) Inventor: Wen-Chuang Yu, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ASUSTeK COMPUTER INC., Taipei (TW)

(21) Appl. No.: 11/834,023

(22) Filed: Aug. 6, 2007

(30) Foreign Application Priority Data
Sep. 27, 2006 (TW) 95135744

(51) Int. Cl. H05K 7/14

(52) U.S. Cl. 361/683

(57) ABSTRACT

A portable computer including a display module and an image-capturing module is provided, wherein the image-capturing module is provided on the display module. The image-capturing module includes a pivoting mechanism and an image-capturing device pivotally connected to the pivoting mechanism. The pivoting mechanism has a first pivot part and a second pivot part, and a slot is formed in the second pivot part. The image-capturing device has a third pivot part and a fourth pivot part. The first pivot part is pivotally connected to the third pivot part, and the second pivot part is pivotally connected to the fourth pivot part, wherein the first pivot part and the second pivot part are fixed on the display module.

### CROSS-REFERENCE TO RELATED APPLICATION

This application claims the priority benefit of Taiwan application serial no. 95135744, filed Sep. 27, 2006. All disclosure of the Taiwan application is incorporated herein by reference.

### BACKGROUND OF THE INVENTION

1. Field of the Invention

This invention relates to a portable computer, more particularly, to a portable computer with an image-capturing module.

2. Description of the Related Art

With the development of the science and technology, portable computers such as notebook computers gradually replace desktop computers. Nowadays, some of medium or advanced portable computers usually are equipped with an image-capturing module for users to interact with remote users or record videos of the users themselves.

FIG. 1A is a schematic diagram showing a conventional image-capturing module provided in the housing of a portable computer. FIG. 1B is a schematic diagram showing the image-capturing module shown in the FIG. 1A with some parts being removed. Please refer to FIG. 1A and FIG. 1B simultaneously. The image-capturing module 100 provided in the housing 10 of the portable computer includes a pivoting mechanism 110 and an image-capturing device 120 which is pivotally connected to the housing 10 by the pivoting mechanism 110. Conventionally, the image-capturing angle of the image-capturing device 120 is adjusted by two sliding block 112 and 114 cooperating with each other and a spring 116 of the pivoting mechanism 110. In the conventional technology, the sliding block 112 and the sliding block 114 have corresponding concave surfaces and convex surfaces, respectively. When users rotate the image-capturing device 120, the concave part 112a of sliding block 112 can slide into the convex part 114b from convex part 114a of the sliding block 114, and the spring 116 offers the sliding block 114 a biased pressure to make the sliding block 112 rotate against the sliding block 114. Specifically, the image-capturing angle of the image-capturing device 112 can be adjusted by the cooperation between the sliding block 112 and the sliding block 114.

It is noteworthy that since the capturing angle of the image-capturing device 120 is adjusted by changing the clip position between the sliding block 112 and the sliding block 114 (The concave part 112a of the sliding block 112 slides to the convex 114b from the convex 114a of the sliding block 114.), users cannot freely adjust the capturing angle of the image-capturing device. Moreover, when the concave part 112a of the sliding block 112 slides to the convex 114c from the convex 114a of the sliding block 114, the spring 116 will exert a great biased pressure on the sliding block 114 (compared with the pressure exerted when the concave part of 112a of sliding block 112 slides to the convex part 114b from the convex part 114c of the sliding block 114.). That is to say, when the image-capturing device 120 rotates, the applied force between the spring 116 and the sliding block 114 is not equal, which affects the smoothness of the rotation of the image-capturing module 120.

In addition, a hole 122 is provided on one side of the image-capturing device 120, and a shaft 118 corresponding to the hole 122 is provided in the pivoting mechanism 110. The shaft 118 is provided through the hole 122. What should be noticed is that during the mass production of the products, the mold can not make the hole 122 and shaft 118 in a particular size precisely. That is, a manufacturing tolerance exists between at the hole 122 and the shaft 118. The manufacturing tolerance may cause the hole 122 and the shaft 118 to be loosely-fitted. Then, when users rotate the image-capturing device 120, the pivoted area between the hole 122 and the shaft 118 will shake, which affects the smoothness of the rotation of the image-capturing device 120.

### BRIEF SUMMARY OF THE INVENTION

The objective of this invention is to provide an image-capturing module to make the image-capturing device pivotally connected to the pivoting mechanism rotate smoothly.

The second objective of this invention is to provide an image-capturing module to make the image-capturing device pivotally connected to the pivoting mechanism rotate to a suitable angle as needed.

The third objective of this invention is to provide a portable computer in which the image-capturing module has enhanced rotation smoothness.

To achieve the above or other objectives, this invention provides an image-capturing module suitable for a display module of a portable computer. The image-capturing module includes a pivoting mechanism and an image-capturing device pivotally connected to the pivoting mechanism. The pivoting mechanism has a first pivot part and a second pivot part, and the second pivot part is formed with a slot. The image-capturing device has a third pivot part and a fourth pivot part. The first pivot part is pivotally connected to the third pivot part, and the second pivot part is pivotally connected to the fourth pivot part.

In an embodiment of this invention, the second pivot part is bush, while the fourth pivot part is a shaft.

In an embodiment of this invention, the third pivot part is a hole, while an end of the first pivot part is provided through the hole.

In an embodiment of this invention, the material of the second pivot part is polyethylene (PE).

In an embodiment of this invention, the image-capturing device further includes a lens, an optical detector assembly, and a housing. The lens passes through the housing, and the optical detector assembly is provided in the housing.

In an embodiment of the invention, the material of the housing is acrylonitrile butadiene styrene (ABS).

In an embodiment of the invention, the housing, the fourth pivot part, and the third pivot part are integrally formed.

In an embodiment of the invention, the image-capturing module further includes a fixed seat, and the pivoting mechanism is provided at the fixed seat.

In an embodiment of the invention, the image-capturing module further includes a cover suitable for connecting with the fixed seat to cover the pivoting mechanism.

This invention further provides a portable computer including a display module and the image-capturing module mentioned above. The image-capturing module is provided in the display module. The first pivot part and the second pivot part of the pivoting mechanism are fixed to the display module, and the image-capturing module is pivotally connected to the pivoting mechanism.

In an embodiment of this invention, the fixed seat of the image-capturing module is provided in the display module, and the pivoting mechanism is provided at the fixed seat.

In this invention, the first pivot part of the pivoting mechanism is pivotally connected to the third pivot part of the image-capturing device, while the fourth pivot part of the image-capturing device is pivotally connected to the second pivot part of the pivoting mechanism. Since the second pivot part is formed of softer plastic material and has a slot, it can hold the fourth pivot part effectively. Furthermore, the invention can enhance the rotational smoothness between the image-capturing device and the pivoting mechanism using the material characteristics of the second pivot part and the fourth pivot part, and can hold the image-capturing device at a suitable angular position using the friction between the second pivot part and the fourth pivot part.

These and other features, aspects, and advantages of the invention will become better understood with regard to the following description, appended claims, and accompanying drawings.

### BRIEF DESCRIPTION OF THE DRAWING

FIG. 1A is a schematic diagram showing a conventional image-capturing module provided in the housing of a notebook computer.

FIG. 1B is a schematic diagram showing the image-capturing module shown in the FIG. 1A with some parts removed.

FIG. 2 is a schematic diagram showing a portable computer according to a preferred embodiment of this invention.

FIG. 3A is an assembled view showing the image-capturing module shown in FIG. 2.

FIG. 3B is an exploded view showing the image-capturing module shown in FIG. 2.

FIG. 4A is an assembled view showing another image-capturing module according to a preferred embodiment of this invention.

FIG. 4B is an exploded view showing the image-capturing module shown in FIG. 4A.

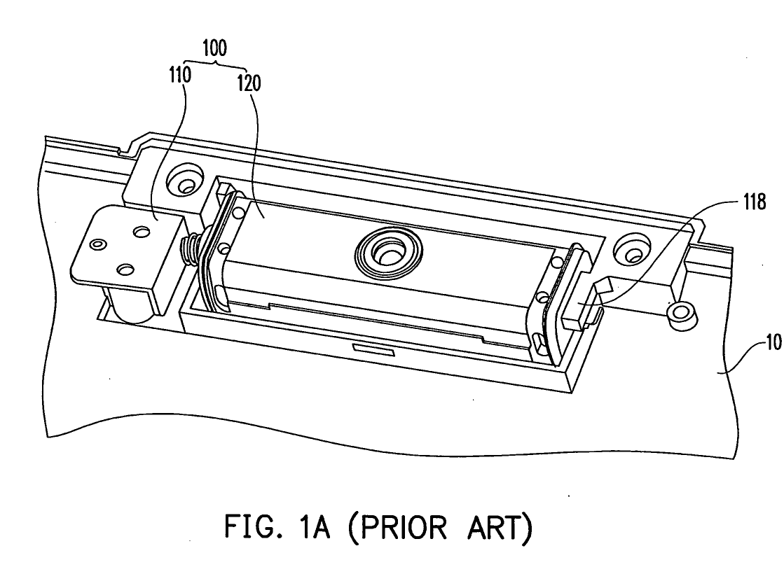

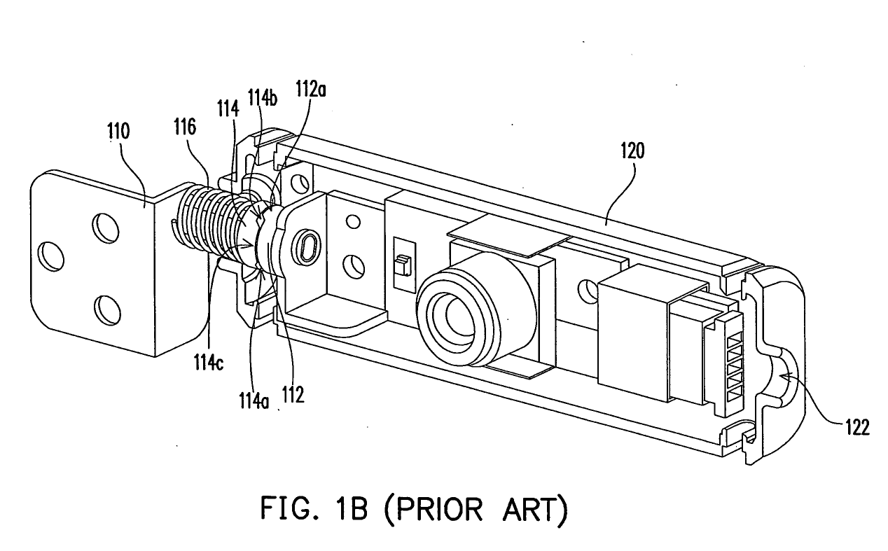

### DETAILED DESCRIPTION OF THE EMBODIMENTS

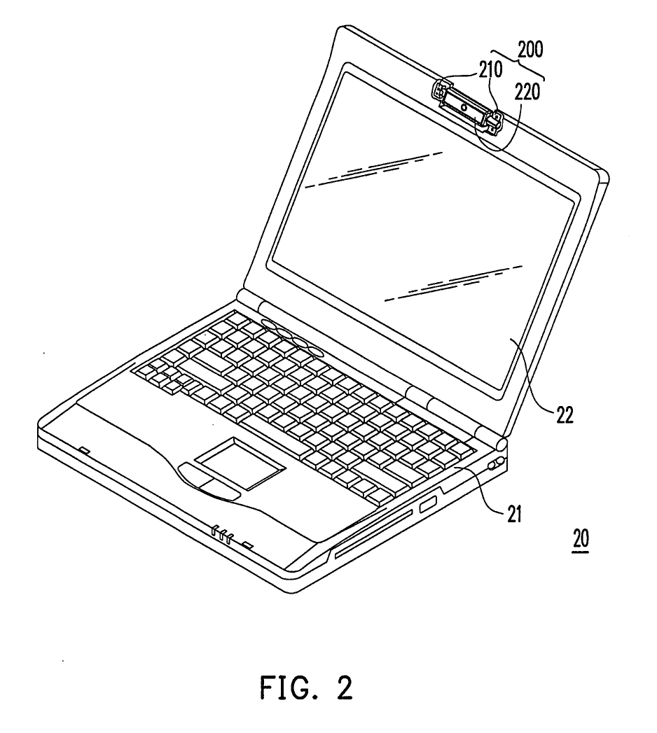

FIG. 2 is a schematic diagram showing a portable computer according to a preferred embodiment of this invention. Please refer to FIG. 2. In this embodiment, the portable computer 20 such as a notebook computer includes a main body 21 and a display module 22, wherein the display module 22 is assembled with an image-capturing module 200. In other embodiment, the portable computer 20 may be a tablet personal computer (tablet PC), a Palmtop, or an ultra-mobile personal computer (UMPC).

In FIG. 2, some parts of the housing of the portable computer 20 have been removed to expose the whole image-capturing module 200. In this embodiment, the image-capturing module 200 provided in the display module 22 can be rotated by users to capture the image they needed.

The image-capturing module 200 of this invention embodiment includes a pivoting mechanism 210 provided in the display module 22 and an image-capturing device 220 pivotally connected to the pivoting mechanism 210. For example, the pivoting mechanism 210 has several through-holes for several screws to pass through to fix the pivoting mechanism in the display module 22. In another embodiment, the pivoting mechanism 210 can also be provided with a clip structure by which the pivoting mechanism 210 can be fixed in the display module 22. This invention has no limitation on how the pivoting mechanism 210 connects to the display module 22. The connection between the image-capturing device 220 and the pivoting mechanism 210 will be described hereinbelow in detail.

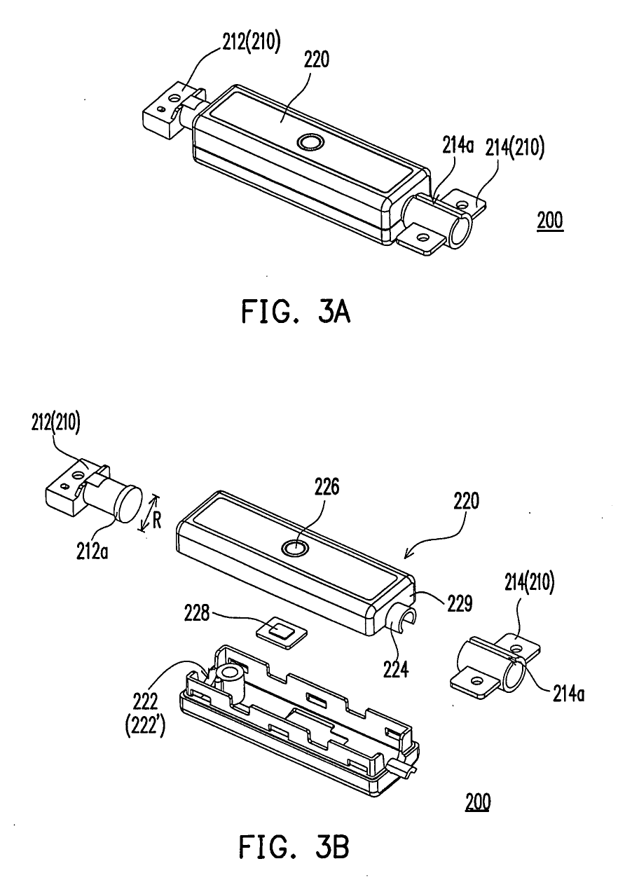

FIG. 3A is an assembled view showing the image-capturing module, and FIG. 3B is an exploded view showing the image-capturing module shown in the FIG. 2. Please refer to FIGS. 3A and 3B simultaneously. The pivoting mechanism 210 of the embodiment includes a first pivot part 212 and a second pivot part 214, and the second pivot part 214 has a slot 214a.

The image-capturing device 220 includes a third pivot part 222 and a fourth pivot part 224, wherein the first pivot part 212 is pivotally connected to the third pivot part 222, and the second pivot part 214 is pivotally connected to the fourth pivot part 224. The pivotal connection between the first pivot part 212 and the third pivot part 222 will be explained first. In this embodiment, the third pivot part 222 can have a hole 222′, while an end 212a of the first pivot part 212 passes through the hole 222′, and the diameter R of the end 212a is larger than the diameter of the hole 222′ as an example. By this way, the end 212a can be tightly-fitted in the hole 222′ with the first pivot part 212 being pivotally connected to the third pivot part 222.

Follow the above, in this embodiment the fourth pivot part 224 of the image-capturing device 220 is pivotally connected to the second pivot part 214 of the pivoting mechanism 210. The above second pivot part 214 is, for example, a bush, and the fourth pivot part 224 is, for example, a shaft.

What should be noticed is, it is noteworthy that during mass production, usually the second pivot part 214 or the fourth pivot part 224 cannot not be made precisely using a mold. That is to say, a manufacturing tolerance exists between the second pivot part 214 and the fourth pivot part 224 mass produced. In addition to, a slot 214a is provided formed in the second pivot part 214 whose material is a suitable softer plastic such as polyethylene. Therefore, when the diameter of the fourth pivot part 224 mass produced is slightly larger than that originally designed, and the diameter of the second pivot part 214 mass produced is slightly smaller than that originally designed, the second pivot part 214 can hold the fourth pivot part 224 by deformation (with the width of the slot 214a becoming larger), while maintaining the relative movement between the second pivot part 214 and fourth pivot part 224.

Please continue to refer to FIG. 3A and FIG. 3B, the image-capturing device 220 of this embodiment further includes a lens 226, an optical detector assembly 228 and a housing 229. The lens 226 passes through the housing 229, while and the optical detector assembly 228 is provided in the housing 229. For example, the optical detector assembly 228 is provided in the light path behind the lens 226, and the optical detector assembly 228 can be a complementary metal oxide semiconductor (CMOS) module, a charge coupled device (CCD) module, or other proper suitable optical module. Moreover, the material of the housing 229 can be, for example, acrylonitrile butadiene styrene (ABS). The above housing 229, the third pivot part 222, and the fourth pivot part 224 can be integrally formed. (That is, the material of the fourth pivot part is ABS.).

Moreover, since the material of the second pivot part 214 and the fourth pivot part 224 are both suitable plastic, a suitable friction force exists between the fourth pivot part 224 and the second pivot part 214 when users rotate the image-capturing device 220 pivotally connected to the pivoting mechanism 210. When users rotate the image-capturing module 220 to a suitable angle, the image-capturing module 220 can be fixed at the position adjusted by the users by the above friction force. The friction force between the second pivot part 214 and the fourth pivot part 224 does not affect the rotation of the image-capturing device 220 on the pivoting mechanism 210. That is, the image-capturing device 220 of this embodiment can rotate on the pivoting mechanism 210 smoothly and be fixed at the position adjusted by the users by the friction force between the second pivot part and the fourth pivot part 224. The users can rotate the image-capturing module 200 as they want to capture the image they need.

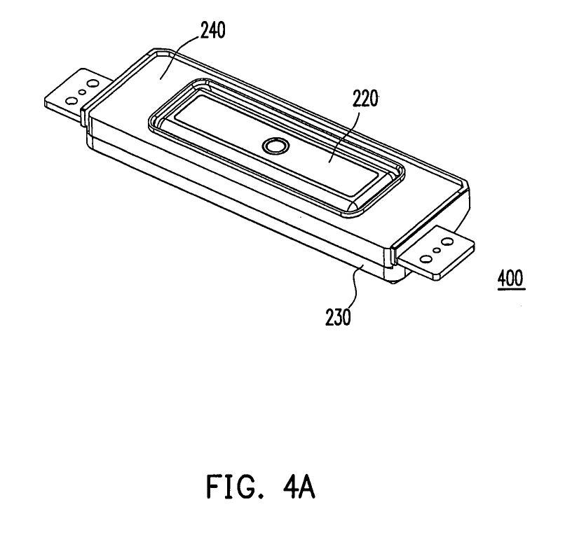

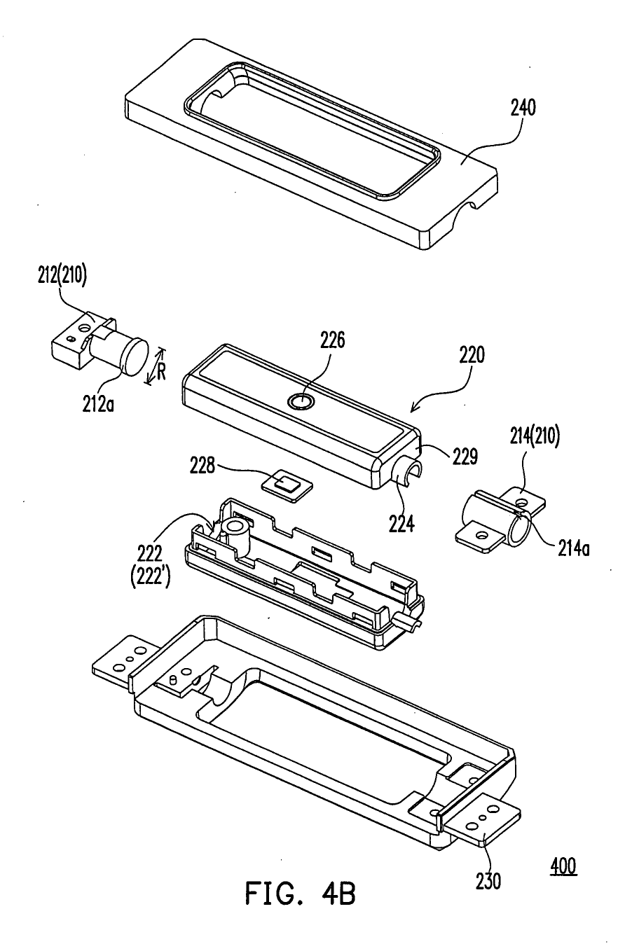

Moreover, the image-capturing module 200 shown in FIGS. 3A and 3B is not the only embodiment of this invention. Other embodiments of this invention will be described below, wherein the same parts will be denoted with the same reference numbers for convenience purpose. FIG. 4A is an assembly view of another image-capturing module according to another embodiment of this invention. FIG. 4B is an exploded view of the image-capturing module shown in the FIG. 4A. Please refer to FIG. 4A and FIG. 4B, the image-capturing module 400 of this embodiment is similar to the image-capturing module 200 of the above embodiment. The difference is that the image-capturing module 400 further includes a fixed seat 230 and a cover 240. In this embodiment, the image-capturing device 220 is also pivotally connected to the pivoting mechanism 210 which is provided in the fixed seat 230, while the fixed seat 230 can be, for example, provided in the display module 22 (shown in FIG. 2). Wherein, persons having ordinary skill in the related art can dispose the fixed seat in a proper position of the display module 22 according to the need of the users to make the users capture images by the image-capturing device 220 conveniently.

In this embodiment, the cover 240 is suitable for connecting with the fixed seat 230 to cover the pivoting mechanism 210 so that the pivoting mechanism 210 will not be easily destroyed by the external force. On the other hand, when the cover 240 covers the fixed seat 230, the cover 240 can make the first pivot part 212 of the pivoting mechanism and the second pivot part 214 fix in the fixed seat 230 more firmly. It is noteworthy that the cover 240 covering the fixed seat 230 can keep the slot 214a provided in the second pivot part 214 to have a fixed width. That is, the second pivot part 214 is not deformed easily so that it does not tend to result in the looseness of the fourth pivot part. In other words, the second pivot part 214 can hold the fourth pivot part 224 more effectively, and the relative movement between the second pivot part 214 and the fourth pivot part 224 can be smooth. The users can rotate the image-capturing module pivotally connected to the pivoting mechanism smoothly to capture the image they need.

To sum up, in the image-capturing module according to the preferred embodiments of this invention, a slot is formed in the second pivot part of the pivoting mechanism made of suitable soft plastic. Therefore, the second pivot part with the slot can be deformed to hold the fourth pivot part of the image-capturing part effectively. In other words, the second pivot part and the fourth pivot part have a good pivotal connection. In addition, the invention can also make the image-capturing device rotate on the pivoting mechanism smoothly by the material characteristics of the second pivot part and the fourth pivot part. Moreover, a suitable friction force exists in the connection of the second pivot part and the fourth pivot part. When the image-capturing device is rotated to a suitable angle, the image-capturing device can be fixed in a suitable position by the above friction force to capture an image. Compared with the conventional technology, the invention has the following advantages:

First, since the preferred embodiment of this invention is to make the image-capturing device pivot at the pivoting mechanism with a simpler design, the image-capturing module of the preferred embodiment of this invention enjoys good assembling efficiency and low cost.

Second, since the second pivot part of the pivoting mechanism and the fourth pivot part of the image-capturing device has a good pivotal connection, the image-capturing module pivotally connected to the pivoting mechanism can rotate smoothly.

Third, a suitable friction force exists between the second pivot part and the fourth pivot part, and the image-capturing module device can be fixed in a suitable position for users to capture images. In other words, users can adjust the angle of the image-capturing device as they wish.

Although the invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A portable computer comprising:
a display module; and
an image-capturing module provided in the display module, the image-capturing module comprising:
a pivoting mechanism comprising a first pivot part and a second pivot part both fixed in the display module, wherein the second pivot part is formed with a slot; and
an image-capturing device pivotally connected to the pivoting mechanism, the image-capturing module comprising a third pivot part and a fourth pivot part, wherein the first pivot part is pivotally connected to the third pivot part, and the fourth pivot part is pivotally connected to the second pivot part.

2. A portable computer according to claim 1, wherein the second pivot part is a bush, and the fourth pivot part is a shaft.

3. A portable computer according to claim 1, wherein the third pivot part is a hole, and one end of the first pivot part passes through the hole.

4. A portable computer according to claim 1, wherein the material of the second pivot part is polyethylene.

5. A portable computer according to claim 1, wherein the image-capturing module further comprises a lens, an optical detector assembly, and a housing passed through by the lens, and the optical detector assembly is provided in the housing.

6. A portable computer according to claim 5, wherein the material of the housing is acrylonitrile butadiene styrene (ABS).

7. A portable computer according to claim 5, wherein the housing, the fourth pivot part, and the third pivot part are integrally formed.

8. A portable computer according to claim 1, wherein the image-capturing module further comprises a fixed seat provided in the display module, and the pivoting mechanism is provided in the fixed seat.

9. A portable computer according to claim 8, wherein the image-capturing module further comprises a cover suitable for connecting with the fixed seat to cover the pivoting mechanism.

10. An image-capturing module suitable for being provided in a display module of a portable computer, comprising:
a pivoting mechanism comprising a first pivot part and a second pivot part, wherein the second pivot part is formed with a slot; and
an image-capturing module pivotally connected to the pivoting mechanism, the image-capturing module comprising a third pivot part and a fourth pivot part, wherein the first pivot part is pivotally connected to the third pivot part, and the fourth pivot part is pivotally connected to the second pivot part.

11. An image-capturing module according to claim 10, wherein the second pivot part is a bush, and the fourth pivot part is a shaft.

12. An image-capturing module according to claim 10, wherein the third pivot part is a hole, and an end of the first pivot part passes through the hole.

13. An image-capturing module according to claim 10, wherein the material of the second pivot part is polyethylene.

14. An image-capturing module according to claim 10, wherein the image-capturing module further comprises a lens, an optical detector assembly, and a housing which is passed through by the lens, and the optical detector assembly is provided in the housing.

15. An image-capturing module according to claim 14, wherein the material of the housing is acrylonitrile butadiene styrene (ABS).

16. An image-capturing according to claim 14, wherein the housing, the third pivot part and the fourth pivot part are integrally formed.

17. An image-capturing module according to claim 10 further comprising a fixed seat, and the pivoting mechanism is provided in the fixed seat.

18. An image-capturing module according to 17 further comprising a cover suitable for connecting with fixed seat to cover the pivoting mechanism.
